(19) United States
(12) Patent Application Publication
(10) Pub. No.: US 2015/0020998 A1
(43) Pub. Date: Jan. 22, 2015

(54) CYCLING HEAT DISSIPATION MODULE

(71) Applicant: Acer Incorporated, New Taipei CIty (TW)

(72) Inventors: Cheng-Wen Hsieh, New Taipei City (TW); Wen-Neng Liao, New Taipei City (TW)

(73) Assignee: Acer Incorporated, New Taipei City (TW)

(21) Appl. No.: 14/098,486

(22) Filed: Dec. 5, 2013

(30) Foreign Application Priority Data
Jul. 18, 2013 (TW) 102125778

(51) Int. Cl. H05K 7/20

(52) U.S. Cl. CPC H05K 7/20336
USPC 165/104.21

(57) ABSTRACT

A cycling heat dissipation module is used for removing the heat generated by a heat generating element and includes at least one main body and at least one conducting pipe. The main body has a chamber and a heat guiding part. The chamber is filled with fluid and has a wall to divide the chamber into a first compartment and a second compartment connected to each other. The first compartment has a first outlet, and the second compartment has a first inlet. The heat guiding part is used for conducting the heat generated from the heat generating element. The conducting pipe has a first end, a second end and a heat exchanging section. The fluid is pushed into the heat exchanging section by a pressure difference after absorbing the heat of the heat guiding part. After it is cooled, the fluid is flowed back to the chamber.

### CROSS-REFERENCE TO RELATED APPLICATION

This application claims the priority benefit of Taiwan application serial no. 102125778, filed on Jul. 18, 2013. The entirety of the above-mentioned patent application is hereby incorporated by reference herein and made a part of this specification.

### FIELD OF INVENTION

The invention is related to a cycling heat dissipation module, and more particularly, to a cycling heat dissipation module that absorbs heat by using fluid.

### Description of Related Art

As technology advances, portable electronic devices have been trending to be thinner and lighter. For example, notebook computers, tablet PCs, and smart phones that are thinner and lighter are more convenient to be carried around and operated on. Taking a tablet PC for example, a tablet PC has the features of being small and light, which is convenient for a user to use as a portable device. In order to improve the processing efficiency of the tablet PC, the efficiency of the central processor of the motherboard is also raised. When the central processor is executing a higher requirement operation, a large amount of heat energy is generated. In order to prevent the heat energy from affecting the central processor, a heat dissipation system will be disposed within a tablet PC, so as to remove the heat generated by the heat generating units.

In general, heat dissipation systems include air-cooled dissipation systems and water-cooled dissipation systems. Water-cooled dissipation systems have better efficiency. Water-cooled cycling heat dissipation modules use a thermal contact to directly contact the back side of a heating emitting unit (such as the central processing unit). A coolant pipe is used to correspondingly connect to the thermal contact and the inner pipes of a heat exchanger. This way, the heat energy transfers from the cycling heat dissipation module to the heat exchanger, achieving the goal of water cooling. However, as there are now more and more restrictions to the space allowed in a tablet PC, a heat exchanger is too large, and is not suitable in a tablet PC. Thus, how to dispose a water-cooled heat dissipation system in limited space has become an important topic.

### SUMMARY OF THE INVENTION

The invention provides a cycling heat dissipation module that uses fluid to absorb heat generated by a heat generating element. After the fluid is cooled away from the heat generating element, it is then flowed back to the cycling heat dissipation module.

The cycling heat dissipation module is used to remove the heat generated by a heat generating element of a circuit board. The cycling heat dissipation module includes at least one main body and at least one conducting pipe. The main body includes a chamber and a heat guiding part. The chamber is disposed in the main body. The chamber is filled with fluid and has a wall to divide the chamber into a first compartment and a second compartment communicated with each other. The first compartment has a first outlet, and the second compartment has a first inlet. The fluid is suitable for moving between the first compartment and the second compartment. At least one first side wall of the chamber is contacted with the heat guiding part, wherein the heat guiding part is used for conducting the heat generated from the heat generating element. The conducting pipe includes a first end, a second end and a heat exchanging section. The first end is connected to the first outlet, and the second end is connected to the first inlet. The heat exchanging section connects the first end and the second end. After the fluid in the chamber has absorbed the heat conducted from the first side wall, the fluid is pushed into the heat exchanging section of the conducting pipe through the first outlet by a pressure difference. After the fluid is cooled, it is then pushed back into the chamber through the first inlet by a pressure difference.

Based on the above, in the cycling heat dissipation module of the invention, the fluid flows in the chamber of the main body. The heat guiding part of the main body can absorb the heat generated from a heat generating element, and conduct the heat to the fluid. After the fluid absorbs the heat generated from the heat generating element, the fluid exits from the first outlet of the first compartment and enters the heat exchanging section. The fluid is cooled in the heat exchanging section, and is then returned to the main body by flowing into the second compartment through the first inlet. Thus, the heat dissipating apparatus of the invention can reduce the volume of a water-cooled heat dissipating system, so as to be more suitable for a thinner notebook computer or tablet PC.

To make the above features and advantages of the invention more comprehensible, several embodiments accompanied with drawings are described in detail as follows.

### BRIEF DESCRIPTION OF THE DRAWINGS

FIG. 1A is a schematic view of a cycling heat dissipation module according to an embodiment of the invention.

FIG. 1B is a schematic cross-sectional view taken along line I-I in FIG. 1A.

FIG. 1C is an enlarged partial view of FIG. 1B.

FIG. 2A is a schematic view of a cycling heat dissipation module according to another embodiment of the invention.

FIG. 2B is a schematic cross-sectional view taken along line I-I in FIG. 2A.

FIG. 2C is a schematic view of the cycling heat dissipation module of FIG. 2A disposed in an electronic device.

FIG. 3 is a schematic view of the cycling heat dissipation module of FIG. 2C in use.

### DESCRIPTION OF EMBODIMENTS

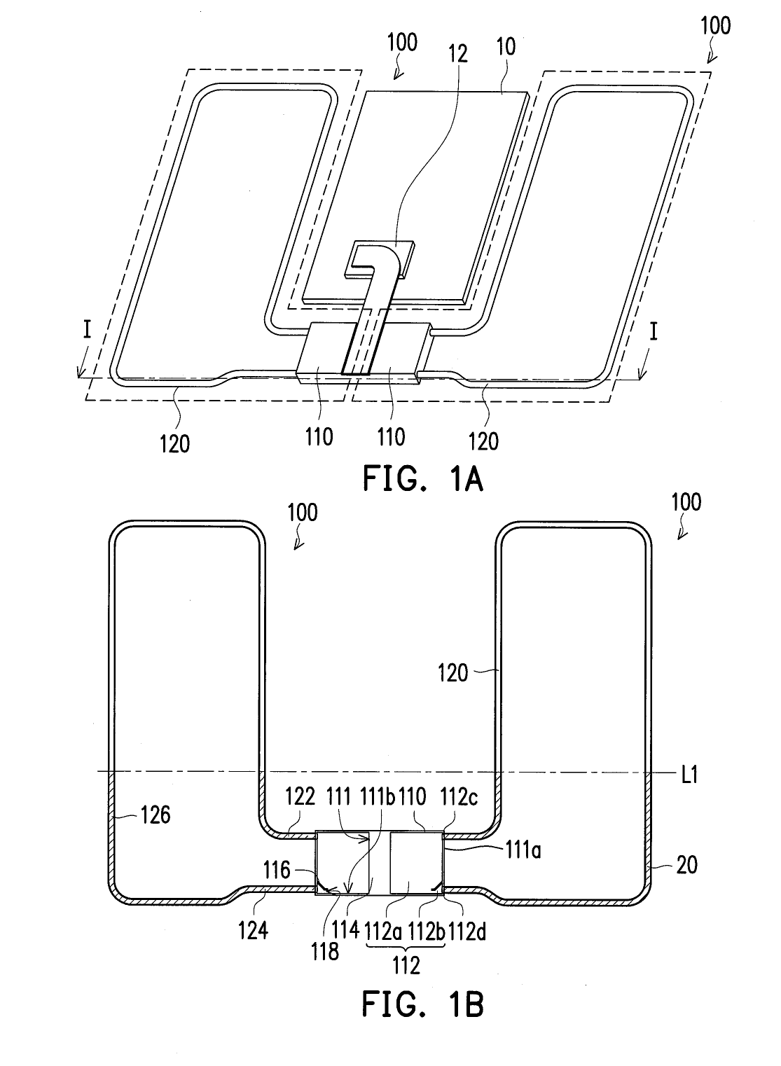

FIG. 1A is a schematic view of a cycling heat dissipation module according to an embodiment of the invention. FIG. 1B is a schematic cross-sectional view taken along line I-I in FIG. 1A. FIG. 1C is an enlarged partial view of FIG. 1B. Referring to FIG. 1A, FIG. 1B, and FIG. 1C, the cycling heat dissipation module 100 of the embodiment is used to remove the heat generated by a heat generating element 12 of a circuit board 10. The cycling heat dissipation module 100 includes at least one main body 110 and at least one conducting pipe 120. The main body 110 includes a chamber 112 and a heat guiding part 114. The chamber 112 is filled with fluid 20 and has a wall 116 to divide the chamber 112 into a first compartment 112a and a second compartment 112b communicated with each other. The first compartment 112a has a first outlet 112c, and the second compartment 112b has a first inlet 112d. The fluid 20 is suitable for moving between the first compartment 112a and the second compartment 112b. At least one first side wall 111 of the chamber 112 is contacted with the heat guiding part 114, wherein the heat guiding part 114 is used for conducting the heat generated from the heat generating element 12.

The conducting pipe 120 includes a first end 122, a second end 124 and a heat exchanging section 126. The first end 122 is connected to the first outlet 112c, and the second end 124 is connected to the first inlet 112d. The heat exchanging section 126 connects the first end 122 and the second end 124. After the fluid 20 has absorbed the heat conducted from the first side wall 111, the fluid 20 is pushed into the heat exchanging section 124 of the conducting pipe 120 through the first outlet 112c by a pressure difference. After the fluid 20 is cooled, it is then pushed back into the second compartment 112b through the first inlet 112d by a pressure difference.

Further referring to FIG. 1A to FIG. 1C, the cycling heat dissipation module 100 of the embodiment is applied on a circuit board 10 of a tablet PC type electronic device. The heat generating element 12 of the circuit board 10 is for example, a central processing unit (CPU). The heat exchanging section 126 can be away from the circuit board 10 and close to the periphery of the electronic device. In the chamber 112, the wall 116 protrudes from a second side wall 111a of the chamber 112, so as to divide the chamber 112 into a first compartment 112a and a second compartment 112b communicated with each other. In addition, in the cycling heat dissipation module 100, the wall 116 of the chamber 112 not only divides the chamber 112 into the first compartment 112a and the second compartment 112b, but also makes up a narrow channel 118 with the chamber 112. Furthermore, the fluid 20 is prevented from flowing from the first compartment 112a to the second compartment 112b. At a location in the second compartment 112b close to the narrow channel 118, the cross sectional area of the second compartment 112b has a gradually shrinking design. As the second compartment 112b is closer to the narrow channel 118, the cross sectional area becomes smaller, increasing the flow velocity of the fluid 20. In the embodiment, the side wall which forms a part of the narrow channel 118 can be a side wall of the main body 110 or the heat guiding part 114. For example, in the cycling heat dissipation module 100, the wall 116 and a bottom side wall 111b both make up the narrow channel 118. However, the invention is not limited thereto.

When the heat of the heat generating element 12 is conducted to the heat guiding part 114, the fluid 20 of the chamber 112 can absorb the heat conducted by the heat guiding part 114. After the fluid is vaporized, it enters the heat exchanging section 126 of the conducting pipe 120 through the first outlet 112c. After the fluid 20 is condensed into liquid, it then flows into the second compartment 112b through the first inlet 112d. Thus, the volume of the cycling heat dissipating apparatus 100 of the embodiment is reduced by not requiring additional heat dissipation holes, so as to be more suitable for a thinner notebook computer or tablet PC. In addition, the cycling heat dissipation module 100 of the embodiment uses the fluid 20 to absorb the heat transmitted to the heat guiding part 114, and then evaporate the fluid 20 to create a fluid cycle. This further reduces the noise problem of heat dissipation.

In FIG. 1A and FIG. 1B, in order to increase the heat dissipation efficiency, multiple cycling heat dissipation modules 100 can be symmetrically configured to form a heat dissipation system. This way, the electronic device can have efficient heat dissipation under different operations. However, the invention does not limit the shape and the configuration of the cycling heat dissipation modules 100. For example, in an undrawn embodiment of the invention, when a plurality of cycling heat dissipation modules are set up, the cycling in the chamber and the conducting pipe of these cycling heat dissipation modules are independent. The arrangement of the chambers of the cycling heat dissipation module can be arranged in parallel, intersecting, in the shape of a window, or have multiple sides, and is not limited to the parallel arrangement shown in the drawings. The following provides another embodiment to describe a variation in the application of the embodiment of FIG. 1A.

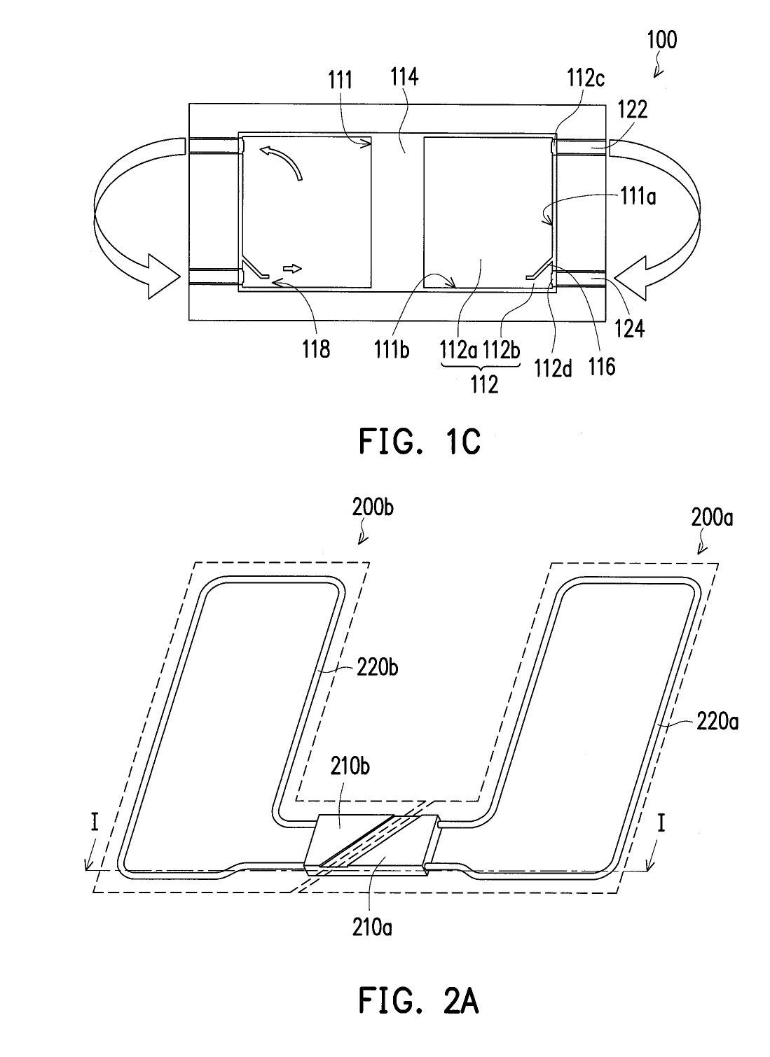

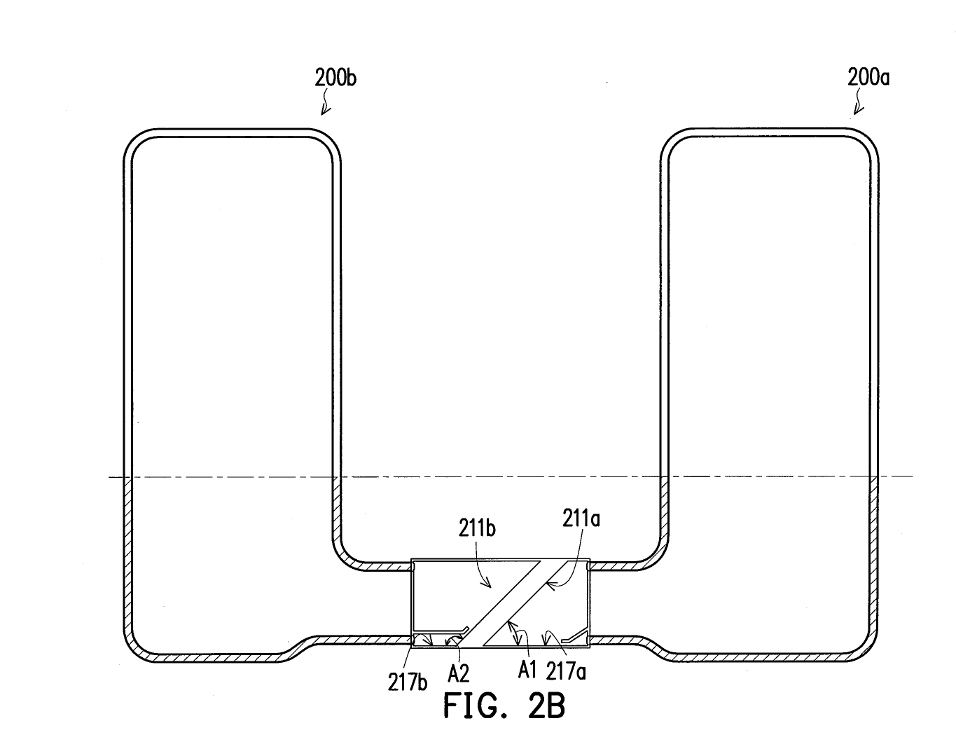

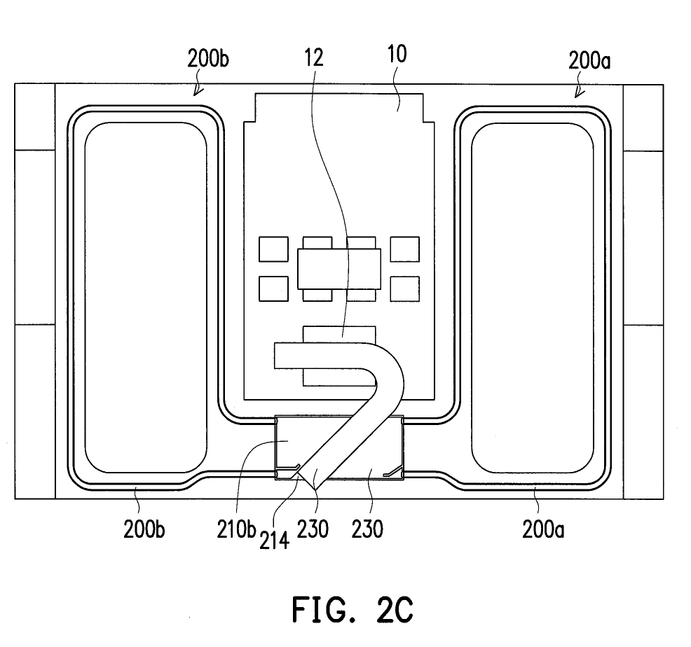

FIG. 2A is a schematic view of a cycling heat dissipation module according to another embodiment of the invention. FIG. 2B is a schematic cross-sectional view taken along line I-I in FIG. 2A. FIG. 2C is a schematic view of the cycling heat dissipation module of FIG. 2A disposed in an electronic device. Please refer to FIG. 2A to FIG. 2C. In the embodiment, the walls 213a and 213b have the same shape as the embodiment shown in FIG. 1A, and will not be repeated hereinafter. The electronic device performs heat dissipation through a heat dissipation system made up of the cycling heat dissipation modules 200a, 200b. The cycling heat dissipation modules 200a, 200b have shapes that supplement each other. In detail, as seen in FIG. 2B, a first side wall 211a of the cycling heat dissipation module 200a and the bottom side wall 217a of the chamber 212a connected with the first side wall 211a forms an angle A1. The angle A1 is an acute angle. Relative to the cycling heat dissipation module 200a, a first side wall 211b of the complementary heat dissipation module 200b and a bottom side wall 217b form an angle A2. The angle A2 of the cycling heat dissipation module 200b is an obtuse angle.

In FIG. 2C, the cycling heat dissipation modules 200a, 200b both form the heat conducting pipe 214 and use a common extension element 230. A concave of the heat conducting pipe 214 of the cycling heat dissipation modules 200a, 200b is also formed by both of the cycling heat dissipation modules 200a, 200b. The extension element 230 is contained in the concave. In other words, the cycling heat dissipation modules 200a, 200b can contact the heat generating element 12 by way of the extension element 230 extending from the main bodies 210a, 210b. This allows the cycling heat dissipation modules 200a, 200b to not have to be disposed on the circuit board 10, thus increases the flexibility in configuring the space within the electronic device. In the embodiment, the extension element 230 and the main bodies 210a, 210b are different components connected to each other. However, the invention is not limited thereto. In another embodiment of the invention not shown in the drawings, the main bodies and the extension element can be one component formed together. The material of the main bodies 210a, 210b of the cycling heat dissipation modules 200a, 200b can be metal, manufactured by way of die-casting. However, the invention is not limited thereto.

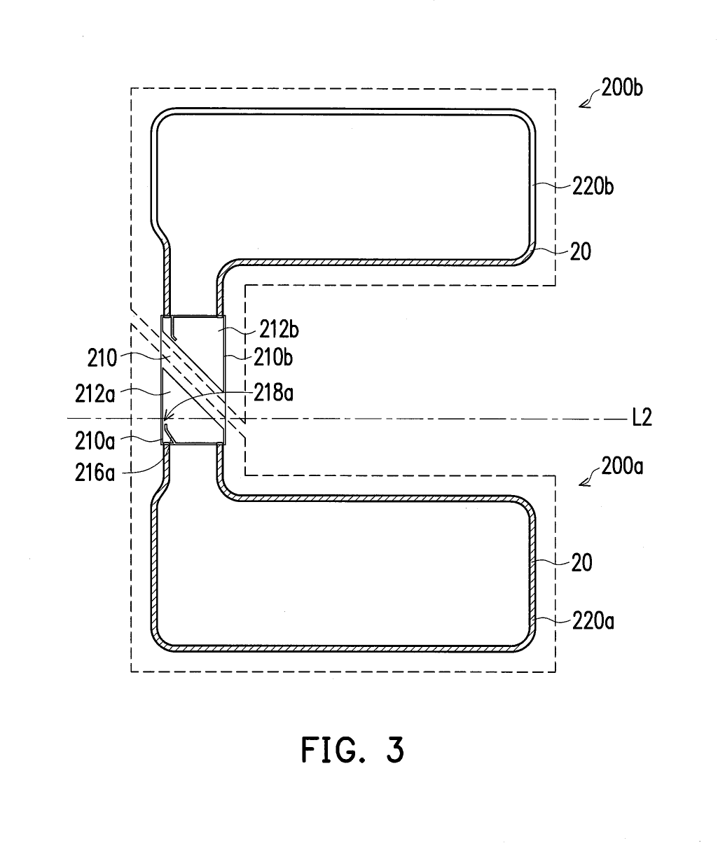

FIG. 3 is a schematic view of the cycling heat dissipation module of FIG. 2C in use. Referring to FIG. 2B and FIG. 3, in FIG. 2B, the liquid line L1 shows the liquid height of the fluid 20 respectively filling the cycling heat dissipation modules 200a, 200b. When the cycling heat dissipation modules 200a, 200b are horizontal (as shown in FIG. 2B), the fluid 20 fills the main body and part of the conducting pipes 220a, 220b. This ensures that the fluid 20 can undergo a gas-liquid one way cycle. In the embodiment, the volume of the fluid 20 is over 30% of the total volume of the chamber 212a, 212b and the conducting pipe 220a, 220b. Preferably, the volume of the fluid 20 is 50% of the total volume of the chamber 212a, 212b and the conducting pipe 220a, 220b. However, the invention is not limited thereto.

The amount filled by the fluid 20 can further ensure that when the cycling heat dissipation modules 200a, 200b are rotated to be upright as shown in FIG. 3, such as when the electronic device is being vertically used, the fluid 20 in the chamber respectively covers the opening of the narrow channel 218a of the first chamber 212a. In other words, fluid 20 at a lower region can continuously fill the corresponding conducting pipe 220a, and the liquid line L2 of the fluid 20 is higher the opening of the narrow channel 218a formed by the wall 216a and the chamber 212a. This allows the fluid 20 in the chamber 212a to still be able to absorb the heat of the heat guiding part 214 after the heat guiding part 214 absorbs the heat from the heat generating element 12, and undergo evaporation and enter the conducting pipe 220a for cooling.

Based on the above, in the cycling heat dissipation module of the invention, the fluid flows in the chamber of the main body. The heat guiding part of the main body can transmit the heat generated from a heat generating element, and conduct the heat to the fluid. After the fluid absorbs the heat generated from the heat generating element, the evaporated fluid exits from the first outlet of the first compartment and enters the heat exchanging section. The fluid is cooled and condensed in the heat exchanging section, and is then returned to the main body by flowing into the second compartment through the first inlet. Thus, the cycling heat dissipating apparatus of the invention can reduce the volume of a water-cooled heat dissipating system, so as to be more suitable for a thinner notebook computer or tablet PC. In addition, the cycling heat dissipation module of the embodiment uses the fluid to absorb the heat transmitted to the heat guiding part, and then evaporate to create a fluid cycle. This further reduces the noise problem of heat dissipation.

Although the invention has been described with reference to the above embodiments, it will be apparent to one of ordinary skill in the art that modifications to the described embodiments may be made without departing from the spirit of the invention. Accordingly, the scope of the invention will be defined by the attached claims and not by the above detailed descriptions.

What is claimed is:

1. A cycling heat dissipation module, adapted to remove heat generated by a heat generating element of a circuit board, the cycling heat dissipation module comprising:
at least one main body, comprising:
at least one chamber, disposed in the at least one main body, wherein the chamber is filled by a fluid and includes a wall, so as to divide the chamber into a first compartment and a second compartment communicated with each other, wherein the first compartment has a first outlet, the second compartment has a first inlet, and the fluid is adapted to flow between the first compartment and the second compartment; and
a heat guiding part, contacted with at least one first side wall of the chamber, wherein the heat guiding part is used for conducting the heat generated from the heat generating element; and
at least one conducting pipe, having a first end, a second end, and a heat exchanging section, wherein the first end is connected to the first outlet, the second end is connected to the first inlet, and the heat exchanging section is connected to the first end and the second end, wherein after the fluid of the chamber absorbs the heat conducted from the at least one first side wall, the fluid is pushed into the heat exchanging section of the conducting pipe through the first outlet by a pressure difference, and after the fluid is cooled, the fluid is then pushed back into the chamber through the first inlet by a pressure difference.

2. The cycling heat dissipation module as claimed in claim 1, wherein the wall of the chamber is extruded from a second side wall opposite to the at least one first side wall, and forms a narrow channel with a side wall of the chamber.

3. The cycling heat dissipation module as claimed in claim 2, wherein a cross sectional area of the second compartment gradually shrinks as the second compartment is connected closer to the narrow channel.

4. The cycling heat dissipation module as claimed in claim 3, wherein when the cycling heat dissipation module is in an upright condition, the fluid in the chamber covers the narrow channel in the chamber.

5. The cycling heat dissipation module as claimed in claim 1, wherein a volume of the fluid is over 30% of a total volume of the chamber and the conducting pipe.

6. The cycling heat dissipation module as claimed in claim 5, wherein a volume of the fluid is 50% of a total volume of the chamber and the conducting pipe.

7. The cycling heat dissipation module as claimed in claim 1, wherein the first side wall and a bottom side wall of the chamber connected with the first side wall forms an angle.

8. The cycling heat dissipation module as claimed in claim 1, further comprising an extension element, wherein the heat guiding part includes a concave containing the extension element, and the extension element contacts the heat generating element, so that the heat generated from the heat generating element is conducted to the heat guiding part.
